(19) United States
(12) Patent Application Publication
(10) Pub. No.: US 2017/0213766 A1
(43) Pub. Date: Jul. 27, 2017

(54) SEMICONDUCTOR DEVICE AND MANUFACTURING METHOD OF THE SAME

(71) Applicant: Renesas Electronics Corporation, Tokyo (JP)

(72) Inventor: Junichi KITAYAMA, Ibaraki (JP)

(21) Appl. No.: 15/359,586

(22) Filed: Nov. 22, 2016

(30) Foreign Application Priority Data
Jan. 27, 2016 (JP) 2016-013573

(51) Int. Cl. H01L 21/78; H01L 29/40; H01L 21/304; H01L 29/41

(52) U.S. Cl. CPC H01L 21/78; H01L 29/41; H01L 29/401; H01L 21/3043

(57) ABSTRACT

A manufacturing method of a semiconductor device forms grooves on a surface side of a semiconductor substrate and thereafter performs grinding from a back side of the semiconductor substrate until a ground face reaches the grooves. Thereafter, a back electrode is formed on the back of the semiconductor substrate that is separated by the grinding.

### CROSS-REFERENCE TO RELATED APPLICATIONS

The disclosure of Japanese Patent Application No. 2016-013573 filed on Jan. 27, 2016 including the specification, drawings and abstract is incorporated herein by reference in its entirety.

### BACKGROUND

The present invention relates to a semiconductor device and a manufacturing technique for the same, and relates to a technique that is effective when being applied to a semiconductor device including a back electrode on a back of a semiconductor chip, for example.

WO/2005/022609 (Patent Literature 1) describes a technique that puts an adhesive film onto a surface of a semiconductor wafer and then forms a metal film on a back of the semiconductor wafer.

Japanese Unexamined Patent Application Publication No. 2002-016021 (Patent Literature 2) and Japanese Unexamined Patent Application Publication No. 2014-183097 (Patent Literature 3) describe a technique related to a so-called “Dicing Before Grinding” in which dicing is performed prior to grinding of the back of the semiconductor wafer.

### SUMMARY

Nowadays a semiconductor chip with a power transistor formed therein employs a structure that makes a current flow in a thickness direction of the semiconductor chip, and therefore a back electrode of a metal film is formed on a back of the semiconductor chip. Further, in order to reduce an on state resistance of the power transistor, the semiconductor chip with the power transistor formed therein has been further thinned.

The thus configured semiconductor chip is manufactured by the following steps, for example. Grinding of a back of a semiconductor wafer is performed so that the semiconductor wafer is thinned, and thereafter the back electrode is formed on the back of the semiconductor wafer. Subsequently, blade dicing is performed for the semiconductor wafer, thereby the semiconductor wafer is separated into a plurality of semiconductor chips.

However, studies by the inventors of the present application revealed that in the above-described steps, dicing of the semiconductor wafer becomes more difficult as the thickness of the semiconductor wafer is reduced. This is because in blade dicing, a dressing effect that conditions a surface of a blade is lowered as the thickness of the semiconductor wafer is reduced. Further, because of the back electrode formed on the back of the semiconductor wafer, clogging of the blade is caused by a soft metal film forming the back electrode. Therefore, by the conventional blade dicing, it has become difficult to separate the thinned semiconductor wafer with the back electrode into a plurality of semiconductor chips.

Other problems and novel features will be apparent from the description of this specification and the accompanying drawings.

In a manufacturing method of a semiconductor device in an embodiment, grooves are formed on a surface side of a substrate, and thereafter grinding is performed from a back side of the substrate to the grooves. Thereafter, a back electrode is formed on the back of the substrate separated by the grinding.

According to the embodiment, a yield of the semiconductor device can be improved.

### BRIEF DESCRIPTION OF THE DRAWINGS

FIG. 1 is a cross-sectional view illustrating a manufacturing step of a semiconductor device in a related art.

FIG. 2 is a cross-sectional view illustrating a manufacturing step of the semiconductor device, following to FIG. 1.

FIG. 3 is a cross-sectional view illustrating a manufacturing step of the semiconductor device, following to FIG. 2.

FIG. 4 is a cross-sectional view illustrating a manufacturing step of the semiconductor device, following to FIG. 3.

FIG. 5 is a cross-sectional view illustrating a manufacturing step of the semiconductor device, following to FIG. 4.

FIG. 6 is a cross-sectional view illustrating a manufacturing step of the semiconductor device, following to FIG. 5.

FIG. 7 is a cross-sectional view illustrating a manufacturing step of the semiconductor device, following to FIG. 6.

FIG. 8 is a cross-sectional view illustrating a manufacturing step of the semiconductor device, following to FIG. 7.

FIG. 9 is a cross-sectional view illustrating a manufacturing step of a semiconductor device in a first embodiment.

FIG. 10 is a cross-sectional view illustrating a manufacturing step of the semiconductor device, following to FIG. 9.

FIG. 11 is a cross-sectional view illustrating a manufacturing step of the semiconductor device, following to FIG. 10.

FIG. 12 is a cross-sectional view illustrating a manufacturing step of the semiconductor device, following to FIG. 11.

FIG. 13 is a cross-sectional view illustrating a manufacturing step of the semiconductor device, following to FIG. 12.

FIG. 14 is a cross-sectional view illustrating a manufacturing step of the semiconductor device, following to FIG. 13.

FIG. 15 is a cross-sectional view illustrating a manufacturing step of the semiconductor device, following to FIG. 14.

FIG. 16 is a cross-sectional view illustrating an outer shape of a semiconductor chip in the first embodiment.

FIG. 17 is a cross-sectional view illustrating an example of a device structure of a unit transistor formed in a cell-forming region.

FIG. 18 is a cross-sectional view illustrating the semiconductor device in the first embodiment.

FIG. 19 is a cross-sectional view illustrating a manufacturing step of a semiconductor device in a first modification.

FIG. 20 is a cross-sectional view illustrating a structure of a semiconductor chip manufactured by a manufacturing method of the semiconductor device in the first modification.

FIG. 21 is a cross-sectional view illustrating a manufacturing step of a semiconductor device in a second modification.

FIG. 22 is a cross-sectional view illustrating a manufacturing step of a semiconductor device in a second embodiment.

FIG. 23 is a cross-sectional view illustrating a manufacturing step of the semiconductor device, following to FIG. 22.

FIG. 24 is a cross-sectional view illustrating a manufacturing step of the semiconductor device, following to FIG. 23.

FIG. 25 is a cross-sectional view illustrating a manufacturing step of the semiconductor device, following to FIG. 24.

FIG. 26 is a cross-sectional view illustrating a manufacturing step of the semiconductor device, following to FIG. 25.

FIG. 27 is a cross-sectional view illustrating a manufacturing step of the semiconductor device, following to FIG. 26.

FIG. 28 is a cross-sectional view illustrating a manufacturing step of the semiconductor device, following to FIG. 27.

FIG. 29 is a cross-sectional view illustrating a manufacturing step of the semiconductor device, following to FIG. 28.

FIG. 30 is a cross-sectional view illustrating a manufacturing step of the semiconductor device, following to FIG. 29.

### DETAILED DESCRIPTION

The following embodiment will be described while being divided into a plurality of sections or embodiments, if necessary for the sake of convenience. However, unless otherwise specified, these are not independent of each other, but are in a relation such that one is a modification example, details, complementary explanation, or the like of a part or the whole of the other.

In the following embodiments, when a reference is made to the number of elements, and the like (including number, numerical value, quantity, range, or the like), the number of elements is not limited to the specific number, but may be the specific number or more or the specific number or less, unless otherwise specified, or except the case where the number is apparently limited to the specific number in principle, or except for other cases.

Further, in the following embodiments, the constitutional elements (including element steps, or the like) are not always essential, unless otherwise specified, or except the case where they are apparently considered essential in principle, or except for other cases.

Similarly, in the following embodiments, when a reference is made to the shapes, positional relationships, or the like of the constitutional elements, or the like, it is understood that they include ones substantially analogous or similar to the shapes or the like, unless otherwise specified, or unless otherwise considered apparently in principle, or except for other cases. This also applies to the foregoing numbers.

Throughout the drawings for explaining embodiments, the same component is labeled with the same reference sign and the redundant description thereof is omitted.

### First Embodiment

### <Description of Terms>

In this specification, a “power transistor” means an assembly of a plurality of unit transistors (cell transistors) that achieve a function of the unit transistor even in a current larger than an allowable current of the unit transistor by being coupled in parallel (for example, several thousands to several hundreds of thousands of the unit transistors coupled in parallel). For example, in a case where the unit transistor serves as a switching element, the “power transistor” serves as a switching element that is also applicable to the current larger than the allowable current of the unit transistor. In particular, the term “power transistor” in this specification is used as a term describing a generic concept including both a “power MOSFET” and an “IGBT”, for example.

### DESCRIPTION OF RELATED ART

First, the description is made to a manufacturing method of a semiconductor device in a related art. Thereafter, matters to be improved in this related art will be described. The “related art” in this specification is a technique having a problem newly found by the inventors, which is not a conventional technique publicly known but is a technique described as premises (unknown art) on which a novel technical idea is based.

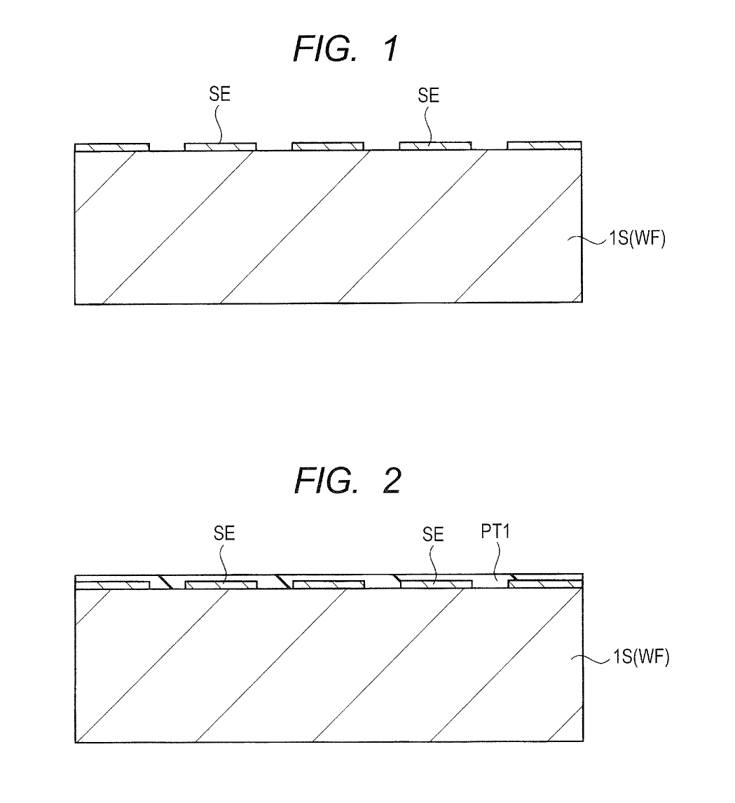

As illustrated in FIG. 1, a semiconductor substrate 1S, for example, formed of silicon (a semiconductor wafer WF) is prepared. A device structure of a “power transistor” is formed on a surface side (an element-forming face side) of the semiconductor substrate 1S. In particular, in FIG. 1, the device structure of the “power transistor” formed on the surface side of the semiconductor substrate 1S is omitted, whereas a source electrode SE electrically coupled to a source of the “power transistor” is illustrated. This source electrode SE is formed by an aluminum film or an aluminum alloy film, for example, and is formed by depositing the aluminum film on the semiconductor substrate 1S and then patterning the aluminum film by using photolithography and etching, for example.

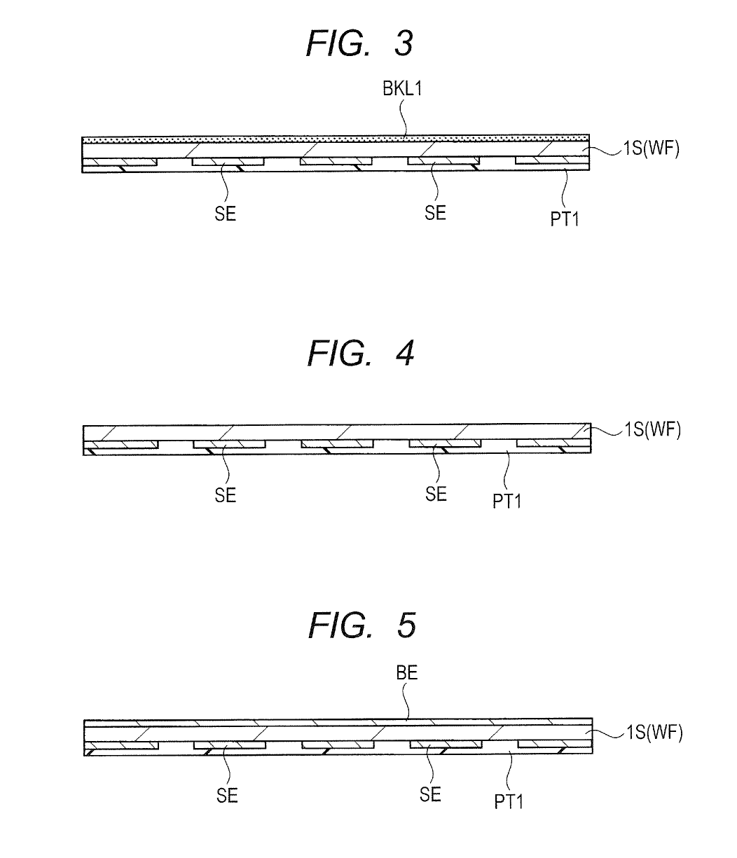

Next, as illustrated in FIG. 2, a surface protection tape PT1 is put to cover the element-forming face of the semiconductor substrate 1S on which the source electrode SE is formed. Thereafter, as illustrated in FIG. 3, the semiconductor substrate 1S is ground from a back that is on the opposite side of the surface of the semiconductor substrate 1S with the surface protection tape PT1 put thereon, by using a grinder, for example. Thus, the semiconductor substrate 1S is thinned. On the back of the semiconductor substrate 1S thus ground, a broken layer BKL1 (a processing strain) is formed by stress during the grinding. When this broken layer BKL1 remains, it is difficult to reduce an on state resistance in an epitaxial layer (a drift layer) in the “power transistor”. Therefore, the broken layer BKL1 is removed, as illustrated in FIG. 4. Specifically, the broken layer BKL1 is removed by a wet process using hydrofluoric acid (stress relief).

Subsequently, as illustrated in FIG. 5, a back electrode BE is formed on the back of the semiconductor substrate 1S from which the broken layer BKL1 has been removed. This back electrode BE is formed by a laminated film of a titanium (Ti) film, a nickel (Ni) film, and a silver (Ag) film or a laminated film of a titanium (Ti) film, a nickel (Ni) film, and a gold (Au) film, for example, and can be formed by sputtering, for example. The surface protection tape PT1 formed to cover the source electrode SE is then peeled off from the semiconductor substrate 1S.

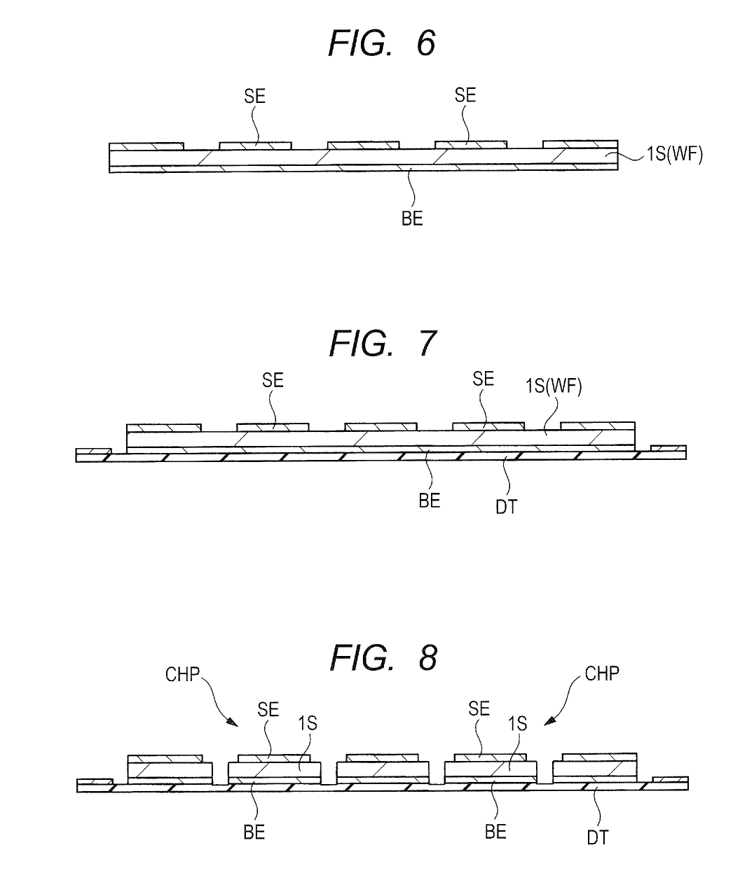

Next, as illustrated in FIG. 7, the semiconductor substrate 1S is arranged on a dicing tape DT in such a manner that the back electrode BE is in contact with the dicing tape DT. Thereafter, as illustrated in FIG. 8, a plurality of chip regions formed in the semiconductor substrate 1S are separated from each other. Specifically, the semiconductor substrate 1S is diced with a blade along scribing regions that section the chip regions, so that a plurality of semiconductor chips CHP are obtained from the semiconductor substrate 1S (semiconductor wafer WF). In this manner, according to the manufacturing method of the semiconductor device in the related art, the semiconductor chips CHP each having the back electrode BE formed thereon can be manufactured.

### <Studies of Improvement>

As described above, the manufacturing method of the semiconductor device in the related art performs dicing, after the semiconductor substrate 1S is thinned and the back electrode is formed. However, studies by the inventors revealed that blade dicing of the semiconductor substrate 1S becomes more difficult according to the method described in the related art, as the semiconductor substrate 1S becomes thinner. In particular, in a case where the blade dicing is performed for the semiconductor substrate 1S that has the back electrode formed on the back thereof and is thinned to 40 μm or less, difficulty in the dicing becomes apparent.

The reason for this is described below. For example, in the blade dicing, the semiconductor substrate 1S is cut while a dicing blade is rotated. In this cutting, a silicon face cut by the dicing blade functions as a grindstone for the dicing blade. In other words, a surface of the dicing blade is conditioned by the silicon face cut by the dicing blade, so that the dicing of the semiconductor substrate 1S is performed while the dicing blade is kept in a good condition. That is, the silicon face cut by the dicing blade has a conditioning function that dresses the surface condition of the dicing blade, and this phenomenon is called a dressing effect. Therefore, the dressing effect by the silicon face is essential in order to achieve good dicing of the semiconductor substrate 1S by the dicing blade. In regard to this point, in a case where the semiconductor substrate 1S is thick, the silicon face is generated sufficiently, making the dressing effect larger. From this, it can be considered that a problem of a dicing failure does not become apparent in the case where the semiconductor substrate 1S is thick.

However, in a case where the semiconductor substrate 1S is thin, an area of the silicon cut face required for achieving the dressing effect cannot be obtained and therefore the dressing effect is lowered. As a result, the problem of the dicing failure becomes apparent in association with thickness reduction of the semiconductor substrate 1S.

Further, the back electrode BE formed on the back of the semiconductor substrate 1S is also one of factors causing the dicing failure. Metal forming the back electrode BE is softer than silicon that includes the semiconductor substrate 1S. The dicing blade is not intended to cut both hard silicon and soft metal that are different in characteristics, and it is therefore difficult for one type of dicing blade to cut both hard silicon and soft metal in a good condition. In addition, in a case where soft metal is cut by the dicing blade that is rotating, the metal clings around the dicing blade because of its softness, causing clogging in the dicing blade. This clogging lowers a cutting performance.

From the reasons described above, according to the method described in the related art, the dicing failure occurs because of synergetic factors of lowering of the dressing effect caused by the thickness reduction of the semiconductor substrate 1S and the clogging caused by use of the dicing blade both for cutting of silicon and cutting of the back electrode BE that is formed of a different type of material. In other words, there are matters to be improved when the method described in the related art is employed as a method for dicing the thinned semiconductor substrate 1S with the back electrode BE formed thereon.

Therefore, in this first embodiment, a method for dicing the thinned semiconductor substrate 1S with the back electrode BE formed thereon is achieved by adopting measures against the matters to be improved in the method described in the related art. In the following description, a technical idea in this first embodiment in which the measures against the matters to be improved are adopted is described, referring to the drawings.

### <Manufacturing Method of Semiconductor Device in First Embodiment>

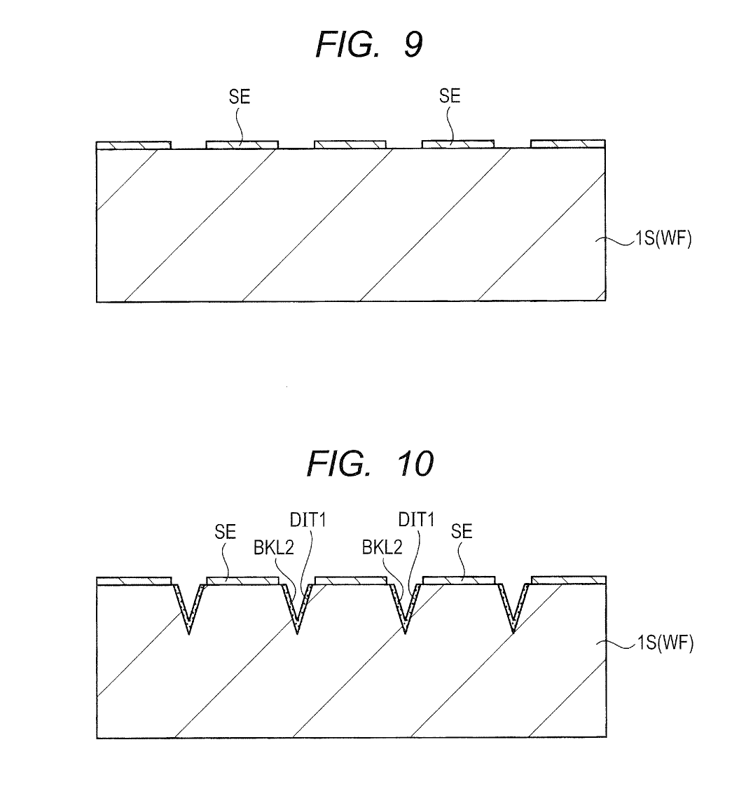

A manufacturing method of a semiconductor device in this first embodiment is described below. First, as illustrated in FIG. 9, a semiconductor substrate 1S (semiconductor wafer WF), for example, formed of silicon is prepared. A device structure of a “power transistor” is formed on a surface side (an element-forming face side) of the semiconductor substrate 1S. The semiconductor substrate 1S includes a plurality of chip regions sectioned by scribing regions as boundary regions. The “power transistor” (a semiconductor element) is formed in each of the chip regions. In particular, in FIG. 9, the device structure of the “power transistor” formed on the surface side of the semiconductor substrate 1S is omitted, whereas a source electrode SE electrically coupled to a source of the “power transistor” is illustrated. This source electrode SE is formed by an aluminum film or an aluminum alloy film, for example, and can be formed by depositing the aluminum film on the semiconductor substrate 1S and then patterning the aluminum film by using photolithography and etching, for example.

Next, grooves DIT1 are formed in the scribing regions sectioning the chip regions, as illustrated in FIG. 10. Specifically, a rotating dicing blade is brought into contact with the scribing region to be pressed against the scribing region, so that the groove DIT1 is formed in the scribing region. A cross-sectional shape of the groove DIT1 is an inverted tapered shape when seen with the element-forming face facing up. That is, the description that “the cross-sectional shape of the groove DIT1 is an inverted tapered shape” means that an angle formed by the surface (the element-forming face) of the semiconductor substrate 1S and the groove DIT1 is larger than 90°. In other words, the description that “the cross-sectional shape of the groove DIT1 is an inverted tapered shape” means that a side face of the groove DIT1 is inclined from the surface (the element-forming face) of the semiconductor substrate 1S to the back thereof in a direction in which the width of the groove DIT1 becomes smaller.

As a specific example, the cross-sectional shape of the groove DIT1 is an inverted triangular shape when seen with the element-forming face facing up, as illustrated in FIG. 10. This groove DIT1 having the inverted triangular shape can be formed by using a dicing blade that has an inverted triangular tip. The cross-sectional shape of the groove DIT1 is not limited to the inverted triangular shape, but may be an inverted trapezoidal shape, for example. In this case, the groove DIT1 having the inverted trapezoidal shape can be formed by using a dicing blade that has an inverted trapezoidal tip. In the formation of the groove DIT1, a broken layer BKL2, which is processing strain, is inevitably formed on an inner wall of the groove DIT1 by stress caused by rotation of the dicing blade, as illustrated in FIG. 10. Note that the inverted triangular shape is defined as a triangle in which its base is arranged above its apex, and the inverted trapezoidal shape is defined as a trapezoidal shape in which an upper base is longer than a lower base.

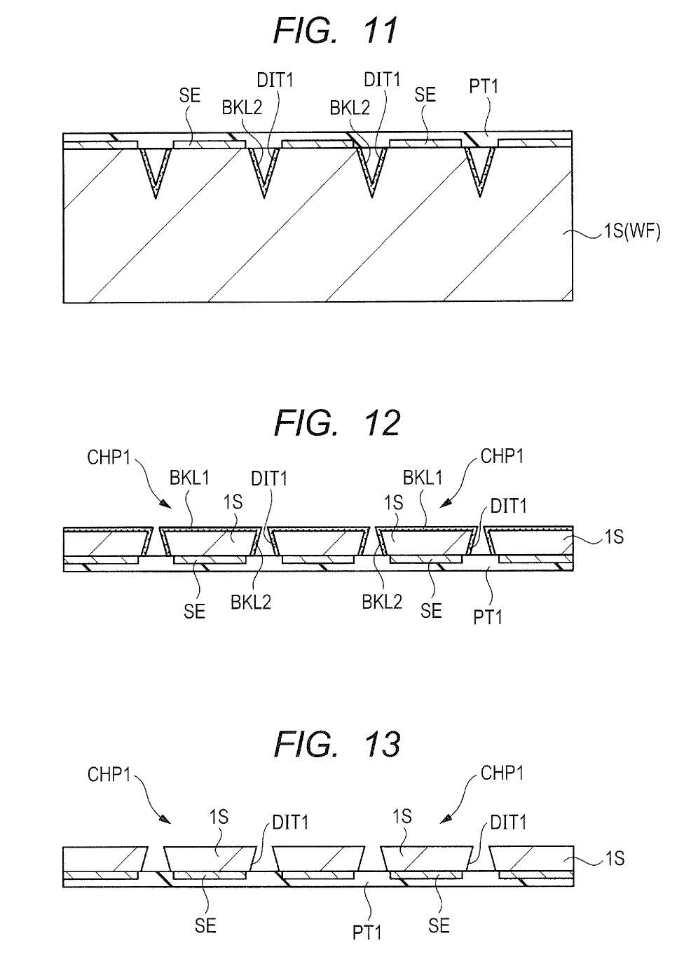

Subsequently, a surface protection tape PT1 covering the source electrode SE is put onto the surface of the semiconductor substrate 1S with the grooves DIT1 formed therein, as illustrated in FIG. 11. Then, grinding of the semiconductor substrate 1S is performed from the back side to the grooves DIT1, as illustrated in FIG. 12. Due to this grinding, the semiconductor substrate 1S is thinned and is then separated into a plurality of semiconductor chips CHP1 at a time when a ground face reaches the grooves DIT1. In this grinding, a broken layer BKL1 is formed by grinding on the back of the semiconductor chip CHP1. Therefore, the individual semiconductor chip CHP1 has the broken layer BKL2 on the side face and the broken layer BKL1 on the back.

Thereafter, as illustrated in FIG. 13, the broken layer BKL1 formed on the back of the individual semiconductor chip CHP1 and the broken layer BKL2 formed on the inner wall of the groove DIT1 that has penetrated (the side face of the individual semiconductor chip CHP1) are removed (a processing strain removal step). In this step, removal of the broken layers BKL1 and BKL2 is performed by a plasma process using a gas, not by a wet process using a chemical liquid, unlike the related art.

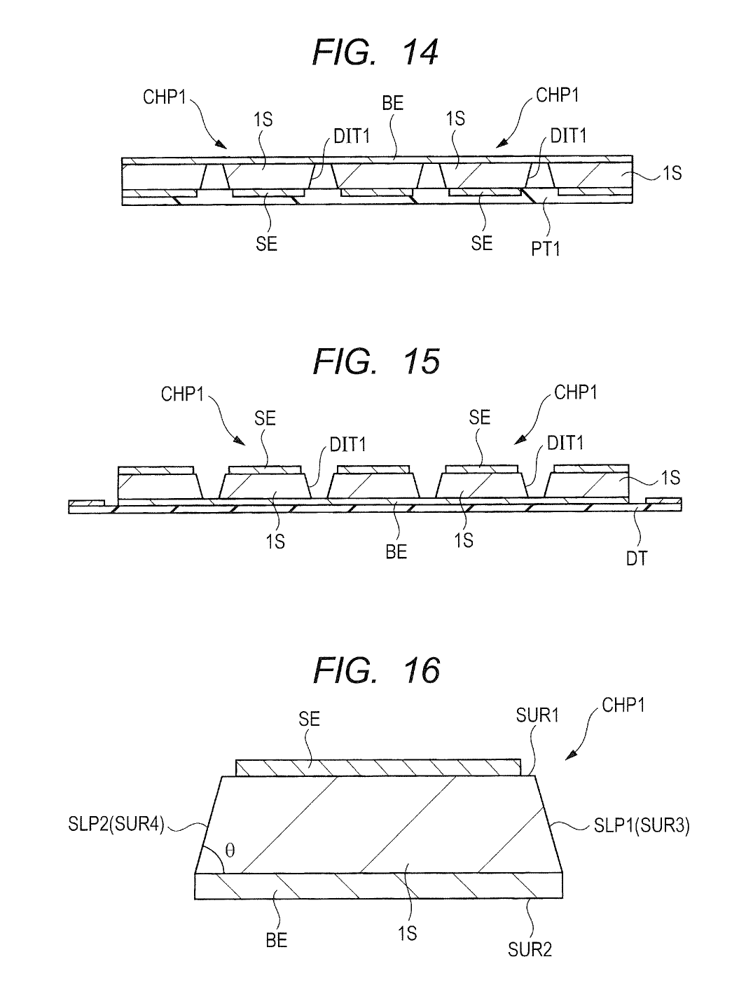

As illustrated in FIG. 14, a back electrode BE is then formed on the back of the semiconductor substrate 1S that has been separated by the back grinding step. In other words, the back electrode BE is formed to spread over backs of the semiconductor chips CHP1. This back electrode BE is formed by a laminated film of a titanium (Ti) film, a nickel (Ni) film, and a silver (Ag) film or a laminated film of a titanium (Ti) film, a nickel (Ni) film, and a gold (Au) film, for example, and can be formed by sputtering, for example. Then, as illustrated in FIG. 15, the surface protection tape PT1 formed to cover the source electrode SE is peeled off from the semiconductor substrate 1S, and thereafter each of the separated semiconductor chips CHP1 is arranged on a dicing tape DT in such a manner that the back electrode BE is in contact with the dicing tape DT.

Subsequently, in the manufacturing method of the semiconductor device in this first embodiment, an expansion step is performed, which broadens gaps between the semiconductor chips CHP1. By the expansion step, in a case where the back electrode SE formed on each of the semiconductor chips CHP1 is continuous, the back electrode BE on each of the semiconductor chips CHP1 is separated from the back electrode BE on another semiconductor chip CHP1. Although FIG. 14 illustrates the back electrode BE integrally formed to spread over the backs of the semiconductor chips CHP1, a situation is not limited thereto. The back electrodes BE formed on the respective semiconductor chips CHP1 may be already separated from each other in the step illustrated in FIG. 14 (the step of forming the back electrode).

According to the manufacturing method of the semiconductor device in this first embodiment, the semiconductor chip CHP1 with the back electrode BE formed thereon can be manufactured in the above-described manner.

### <Features of Method in First Embodiment>

Next, features of the manufacturing method of the semiconductor device in this first embodiment are described. The first feature in this first embodiment is that the back electrode BE is formed on the backs of the semiconductor chips CHP1 after the thinned semiconductor substrate 1S is separated into the semiconductor chips CHP1, as illustrated in FIGS. 13 and 14, for example. In other words, the first feature in this first embodiment is that the thinned semiconductor substrate 1S is separated into the semiconductor chips CHP1 prior to formation of the back electrode BE. Thus, according to this first embodiment, it is not necessary to use one type of dicing blade for both the semiconductor substrate 1S and the back electrode BE that are formed of different materials as in the related art, for example. That is, according to this first embodiment, in manufacturing of the semiconductor chip CHP1 with the back electrode BE formed thereon, the semiconductor substrate 1S is separated into the semiconductor chips CHP1 before the back electrode BE is formed on the back of the semiconductor substrate 1S. Therefore, it is not necessary to consider cutting of the back electrode BE when the semiconductor substrate 1S is separated into the semiconductor chips CHP1. In other words, according to the first feature in this first embodiment, it is not necessary to cut both silicon including the semiconductor substrate 1S and metal including the back electrode BE, and therefore it is not necessary for one type of dicing blade to cut both hard silicon and soft metal as in the related art. This means that there is a potential for improving a manufacturing yield in the step of separating the semiconductor chips CHP1 by the first feature in this first embodiment, as compared with the related art in which it is necessary to cut both hard silicon and soft metal by means of one type of dicing blade. As described above, a basic idea lying on the basis of the first feature in this first embodiment is to perform the separation step prior to formation of the back electrode BE, not to perform the separation step after formation of the back electrode BE as in the related art. Thus, according to this first embodiment, it is possible to improve the manufacturing yield of the thinned semiconductor chip CHP1 with the back electrode BE.

In particular, this first embodiment uses various measures for embodying the aforementioned first feature. One of the measures is the second feature in this first embodiment. Specifically, the second feature in this first embodiment is that the grooves DIT1 are formed on the surface side of the semiconductor substrate 1S by a rotating dicing blade, as illustrated in FIG. 10, for example, and thereafter the semiconductor substrate 1S is ground from the back side of the semiconductor substrate 1S until the ground face reaches the grooves DIT1, as illustrated in FIG. 12. Due to this feature, the semiconductor substrate 1S can be separated into the thinned semiconductor chips CHP1. For example, in order to obtain the thinned semiconductor chips CHP1, a technique is considered in which the semiconductor substrate 1S is ground to be thinned first, and thereafter dicing of the thinned semiconductor substrate 1S is performed by using a rotating dicing blade, so that the thinned semiconductor chips CHP1 are obtained. However, in this technique, dicing is performed for the thinned semiconductor substrate 1S by using the rotating dicing blade, and a sufficient level of a dressing effect cannot be obtained in this configuration. Therefore, according to this technique, a dicing failure becomes apparent because of lowering of the dressing effect.

To the contrary, in the second feature in this first embodiment, first, the grooves DIT1 are formed on the surface side of the semiconductor substrate 1S that had not been thinned and is therefore thick, by means of a rotating dicing blade, as illustrated in FIG. 10. From this, the dicing blade is used for the thick semiconductor substrate 1S in a step of forming the grooves DIT1, and therefore a sufficient level of the dressing effect can be obtained. Next, in the second feature in this first embodiment, the semiconductor substrate 1S is ground from the back side thereof until the ground face reaches the grooves DIT1, as illustrated in FIG. 12. Thus, while being thinned, the semiconductor substrate 1S is finally separated into the semiconductor chips CHP1 at a time at which the ground face reaches the grooves DIT1.

As described above, the second feature in this first embodiment is to form the grooves DIT1 on the surface side and thereafter grind the semiconductor substrate 1S from the back side to separate the semiconductor substrate 1S into the semiconductor chips CHP1, but does not include a step of dicing the thinned semiconductor substrate 1S by means of a rotating dicing blade. This means that according to this first embodiment a potential for occurrence of a dicing failure caused by lowering of the dressing effect can be avoided. In other words, according to this first embodiment, the step of dicing of the thinned semiconductor substrate 1S by means of the dicing blade is replaced with the step of forming the grooves DIT1 on the surface side and thereafter grinding the semiconductor substrate 1S from the back side. Thus, the reliability of the step of separating the semiconductor substrate 1S into the chips can be surely improved without being affected by clogging caused by cutting of a back electrode by means of the dicing blade. Consequently, according to the second feature in this first embodiment, it is possible to obtain a remarkable effect that the manufacturing yield of the thinned semiconductor chips CHP1 can be improved.

According to the first feature in the first embodiment, the thinned semiconductor substrate 1S is separated into the semiconductor chips CHP1, and thereafter the back electrode BE is formed on the backs of the semiconductor chips CHP1. In this case, there are issues to be considered as described below. In manufacturing steps of the semiconductor device in this first embodiment, the back electrode BE is formed on the back of the semiconductor substrate 1S separated by the grooves DIT1 extending from the surface side to the back side, as illustrated in FIG. 14, for example. The back electrode BE is formed by sputtering, for example. However, because gaps are present between the semiconductor chips CHP1 because of the grooves DIT1, the back electrode BE may be formed not only on the backs of the semiconductor chips CHP1 but also on side faces of the semiconductor chips CHP1 through the gaps. In this case, the source electrode SE formed on the surface of the semiconductor chip CHP1 and the back electrode BE formed on the back of the semiconductor chip CHP1 may be electrically coupled to each other via the undesired back electrode BE formed on the side face of the semiconductor chip CHP1. This means increase of a potential that the source electrode SE of the “power transistor” formed in the semiconductor chip CHP1 and the back electrode BE (a drain electrode) is short-circuited, causing reduction of the reliability of the semiconductor device. In other words, according to the first feature in this first embodiment, it is possible to obtain an advantage that the manufacturing yield of the thinned semiconductor chip CHP1 having the back electrode BE thereon can be improved, whereas a side effect is caused that a short-circuit failure can easily occur between the source electrode SE formed on the surface of the semiconductor chip CHP1 and the back electrode BE formed on the back. Therefore, this first embodiment employs a measure for suppressing this side effect. This measure is the third feature in this first embodiment.

The third feature in this first embodiment is that the cross-sectional shape of the groove DIT1 is an inverted tapered shape when seen with the element-forming face facing up, as illustrated in FIG. 10, for example. Specifically, FIG. 10 illustrates an example in which the cross-sectional shape of the groove DIT1 is an approximately inverted triangular shape. Thus, when grinding is performed from the back side of the semiconductor substrate 1S until the ground face reaches the groove DIT1, the following structure is achieved because of the cross-sectional shape of the groove DIT1 being the inverted tapered shape. As illustrated in FIG. 13, when attention is paid to first and second ones of the semiconductor chips CHP1, that are adjacent to each other, a distance between a back of the first semiconductor chip and a back of the second semiconductor chip is smaller than a distance between an element-forming face of the first semiconductor chip and an element-forming face of the second semiconductor chip. Thus, when the back electrode BE is formed, a gap between the back of the first semiconductor chip and the back of the second semiconductor chip becomes narrow, as illustrated in FIG. 14. This means that the back electrode BE can be hardly formed on a side face of the first semiconductor chip and a side face of the second semiconductor chip via the gap between the first semiconductor chip and the second semiconductor chip. Therefore, according to the third feature in this first embodiment, it is possible to suppress the side effect that the short-circuit failure can easily occur between the source electrode SE formed on the surface of the semiconductor chip CHP1 and the back electrode BE formed on the back. From the above, a combination of the first feature, the second feature, and the third feature in this first embodiment can provide a remarkable effect that while the occurrence of the short-circuit failure between the source electrode SE and the back electrode BE is suppressed, the manufacturing yield of the thinned semiconductor chip CHP1 can be improved.

From a viewpoint of suppressing the short-circuit failure between the source electrode SE and the back electrode BE, it is desirable that the distance between the back of the first semiconductor chip and the back of the second semiconductor chip is as small as possible. Meanwhile, as this distance is made smaller, the back electrodes BE formed on the backs of the semiconductor chips CHP1 can be united more easily. In this case, separation of the semiconductor chips CHP1 is disturbed by the united back electrode BE.

In regard to this point, this first embodiment uses an expansion step that broadens the gaps between the semiconductor chips CHP1 put onto the dicing tape DT by stretching the dicing tape DT, as illustrated in FIG. 15, for example. More specifically, an original function of the expansion step is to broaden the gaps between the semiconductor chips CHP1 put onto the dicing tape DT to enable the individual semiconductor chip CHP1 to be picked up easily. In regard to this point, in the manufacturing method of the semiconductor device in this first embodiment, by using stretching of the dicing tape DT in this expansion step, the united back electrodes BE spreading over the backs of the semiconductor chips CHP1 are separated from each other. That is, the fourth feature in this first embodiment is to separate the back electrodes BE united to spread over the backs of the semiconductor chips CHP1 by using the expansion step that enables the individual semiconductor chip CHP1 to be picked up easily. Thus, according to the fourth feature in this first embodiment, it is unnecessary to newly provide a step for separating the back electrodes BE united to spread over the backs of the semiconductor chips CHP1. Consequently, according to the fourth feature in this first embodiment, separation of the united back electrodes BE can be achieved without making the manufacturing steps complicated. In particular, in a relation between the third feature and the fourth feature in this first embodiment, it is effective to reduce the distance between the backs of the semiconductor chips CHP1 adjacent to each other in order to suppress occurrence of the short-circuit failure between the source electrode SE and the back electrode BE. On the other hand, when the distance between the backs of the semiconductor chips CHP1 adjacent to each other is reduced, the back electrodes BE can be united more easily. However, in regard to this point, it is possible to achieve separation of the united back electrodes BE by the fourth feature without making the manufacturing steps complicated. Therefore, by the organic combination of the third feature and the fourth feature in this first embodiment, it is possible to easily achieve separation of the united back electrodes BE while preventing occurrence of the short-circuit failure between the source electrode SE and the back electrode BE.

Subsequently, the fifth feature in this first embodiment is that a broken-layer removal step that removes the broken layer BKL1 formed on the back of the semiconductor chip CHP1 and the broken layer BKL2 formed on the inner wall of the groove DIT1 employs a plasma process using a gas, as illustrated in FIGS. 12 and 13, for example. For example, the related art employs a wet process using hydrofluoric acid is employed as the broken-layer removal step. However, it is difficult to use this wet process in the manufacturing method of the semiconductor device in this first embodiment. This is because in FIG. 12, for example, there are concerns that a chemical liquid used in the wet process enters to the inside of the groove DIT1, remains in the groove DIT1, and adversely affects the “power transistor” formed on the surface of the semiconductor chip CHP1. In other words, in the manufacturing method of the semiconductor device in this first embodiment, the broken-layer removal step is performed after the semiconductor substrate 1S is separated into the semiconductor chips CHP1, unlike the related art. Therefore, when the liquid chemical is used in the broken-layer removal step in the manufacturing method of the semiconductor device in this first embodiment, a phenomenon that the chemical liquid stays in the gap between the semiconductor chips CHP1 adjacent to each other occurs. Thus, in the manufacturing method of the semiconductor device in the first embodiment, the broken-layer removal step is achieved by the plasma process using a gas, not by the wet process. In this case, because the plasma process uses a gas instead of a liquid, the phenomenon that the liquid remains in the groove DIT1 can be naturally avoided. Consequently, according to this first embodiment, it is possible to remove the broken layer BKL1 formed on the back of the semiconductor chip CHP1 and the broken layer BKL2 formed on the inner wall of the groove DIT1 without the adverse effect caused by the wet process. Thus, according to the fifth feature in this first embodiment, by removing the broken layer BKL1, it is possible to reduce an on state resistance of the “power transistor” without adversely affecting the “power transistor”, and the breaking strength of silicon (Si) can be also improved. In addition, by removing the broken layer BKL2, the breaking strength of silicon (Si) can be further improved.

### <Structure of Semiconductor Chip in First Embodiment>

Next, the description is made to the structure of the semiconductor chip CHP1 manufactured by the aforementioned manufacturing method of the semiconductor device in this first embodiment. FIG. 16 is a cross-sectional view schematically illustrating an outer shape of the semiconductor chip CHP1 in this first embodiment. In FIG. 16, the semiconductor chip CHP1 in this first embodiment includes a surface SUR1 where components of the “power transistor” (semiconductor element) including the source electrode SE are formed and a back SUR2 located on the opposite side of the surface SUR1, on which the back electrode BE is formed. Further, the semiconductor chip CHP1 includes a side face SUR3 coupled to each of the surface SUR1 and the back SUR2 and a side face SUR4 located on the opposite side of the side face SUR3. The side face SUR3 includes a slant portion SLP1 that is inclined with respect to each of the surface SUR1 and the back SUR2. Similarly, the side face SUR4 includes a slant portion SLP2 that is inclined with respect to each of the surface SUR1 and the back SUR2. Thus, in the semiconductor chip CHP1 in this first embodiment, a structure in which a plane area of the back SUR2 is larger than a plane area of the surface SUR1 can be achieved.

In the semiconductor chip CHP1 in this first embodiment illustrated in FIG. 16, an inclination angle θ that is an angle formed by the slant portion SLP1 (SLP2) and the back SUR2 can be set to 25° or more and 85° or less, for example. As specific examples, in a case where the thickness of the semiconductor chip CHP1 is about 40 μm, the inclination angle θ is about 40° to 85°. In a case where the thickness of the semiconductor chip CHP1 is about 30 μm, the inclination angle θ is about 35° to 85°. In a case where the thickness of the semiconductor chip CHP1 is about 20 μm, the inclination angle θ is about 25° to 85°.

### <Device Structure in Semiconductor Chip>

Subsequently, a device structure of the “power transistor” (power MOSFET) formed in the semiconductor chip CHP1 in this first embodiment is described.

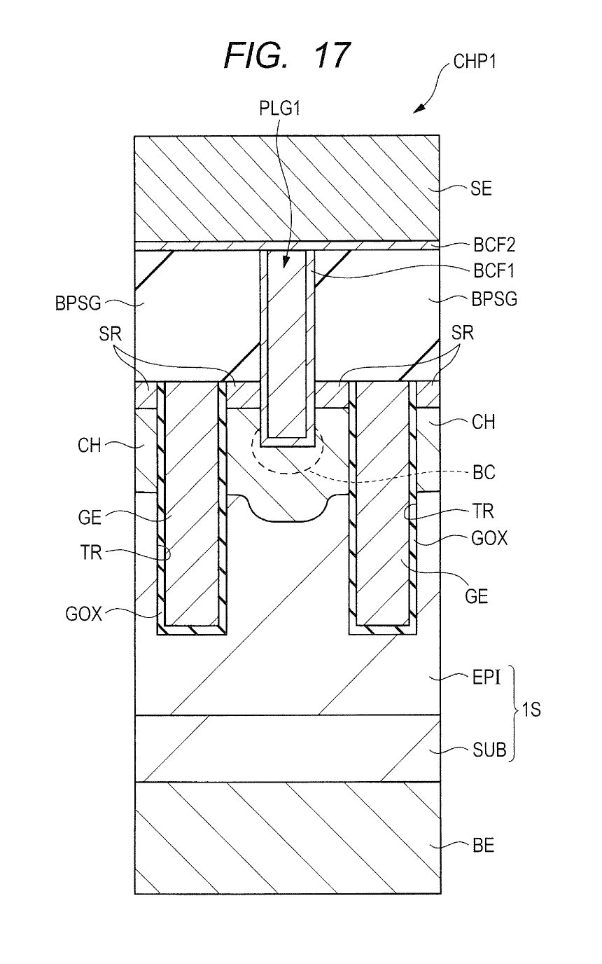

In the semiconductor chip CHP1 in this first embodiment, a power MOSFET that is one type of the “power transistor” is formed, for example. In the following description, a device structure of the power MOSFET is descried, for example. The power MOSFET is configured by coupling several thousands to several hundreds of thousands of unit transistors (cell transistors) in parallel. In FIG. 17 described below, the device structure of the power MOSFET is described, referring to two unit transistors adjacent to each other as an example.

FIG. 17 is a cross-sectional view illustrating an example of a device structure of the unit transistor formed in a cell-forming region. In FIG. 17, an epitaxial layer EPI is formed on a substrate layer SUB made of silicon containing an n-type impurity, such as phosphorous (P) or arsenic (As), for example. This epitaxial layer EPI is formed by a semiconductor layer mainly containing silicon with an n-type impurity, such as phosphorous (P) or arsenic (As), introduced thereinto, for example. The substrate layer SUB and the epitaxial layer EPI are components functioning as a drain of the power MOSFET. In this first embodiment, the substrate layer SUB and the epitaxial layer EPI are collectively referred to as a semiconductor substrate 1S, as illustrated in FIG. 17.

Next, an element portion is formed in a surface of the epitaxial layer EPI. Specifically, in the element portion in this first embodiment, a channel region CH is formed in the surface of the epitaxial layer EPI, and a trench TR is formed to extend through this channel region CH and reach the epitaxial layer EPI. On an inner wall of the trench TR, a gate insulation film GOX is formed. On this gate insulation film GOX, a gate GE is formed to be embedded into the trench TR. The gate insulation film GOX is formed by a silicon oxide film, for example, but is not limited thereto. The gate insulation film GOX can be formed by a high dielectric constant film with a dielectric constant higher than that of the silicon oxide film, for example. The gate GE is formed by a polysilicon film, for example.

Subsequently, a source region SR is formed on the surface of the channel region CH adjacent to the trench TR. An insulation film BPSG is formed to spread over the trench TR with the gate GE embedded thereinto and over the source region SR. The channel region CH is formed by a semiconductor region with a p-type impurity, such as boron (B) introduced thereinto, for example. The source region SR is formed by a semiconductor region with an n-type impurity, such as phosphorous (P) or arsenic (As), introduced thereinto, for example.

Next, a groove is formed between the adjacent trenches RE, which extends through the insulation film BPSG and the source region SR and reaches the channel region CH. On the bottom of this groove, a body contact region BC is formed. This body contact region BC is formed by a semiconductor region with a p-type impurity, such as boron (B), introduced thereinto, for example. The impurity concentration in the body contact region BC is higher than that in the channel region CH.

A barrier conductor film BCF1 and a plug PLG1 formed by a tungsten film are then formed to be embedded into the groove having the body contact region BC formed on the bottom. On the insulation film BPSG including the plug PLG1, a barrier conductor film BCF2 and a source electrode SE formed by an aluminum alloy film are formed. Thus, the source electrode SE is electrically coupled to the source region SR and is also electrically coupled to the channel region CH via the body contact region BC.

The body contact region BC has a function of ensuring an ohmic contact with the plug PLG1. Due to the presence of this body contact region BC, the source region SR and the channel region CH are electrically coupled to each other at the same potential.

Therefore, it is possible to suppress an on operation of a parasitic npn bipolar transistor that includes the source region SR as an emitter region, the channel region CH as a base region, and the epitaxial layer EPI as a collector region. That is, the fact that the source region SR and the channel region CH are electrically coupled to each other at the same potential means that no potential difference is generated between the emitter region and the base region of the parasitic npn bipolar transistor. Due to this, the on operation of the parasitic npn bipolar transistor can be suppressed.

Subsequently, the back electrode BE is formed on the back of the substrate layer SUB, as illustrated in FIG. 17.

As described above, the device structure of the power MOSFET is formed inside the semiconductor chip CHP1 in this first embodiment.

In the power MOSFET formed inside the semiconductor chip CHP1, a body diode that is a parasitic diode is formed by the epitaxial layer EPI that is an n-type semiconductor layer and the channel region CH that is a p-type semiconductor layer. In other words, the body diode that is a pn junction diode including the channel region CH as an anode and the epitaxial layer EPI as a cathode is formed between the epitaxial layer EPI and the channel region CH.

### <Package Structure of Semiconductor Device in First Embodiment>

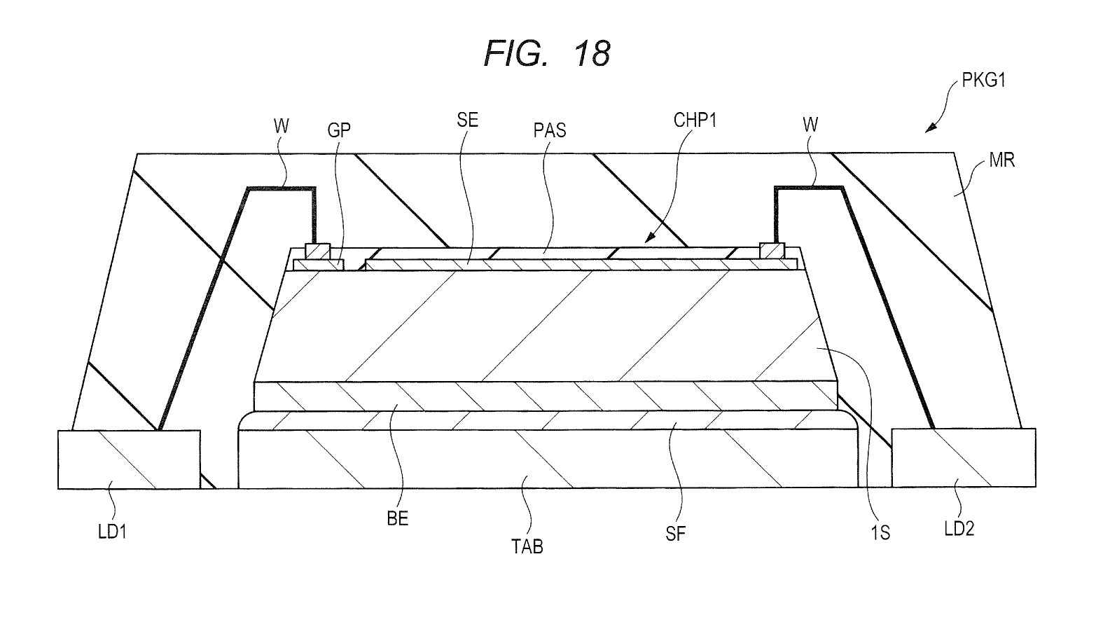

Next, a package structure of a semiconductor device PKG1 in this first embodiment is described. FIG. 18 is a cross-sectional view schematically illustrating the semiconductor device PKG1 in this first embodiment. In FIG. 18, the semiconductor device PKG1 in this first embodiment includes a lead LD1 and a lead LD2 that are away from each other, and a chip-mounting portion TAB. On the chip-mounting portion TAB, the semiconductor chip CHP1 is mounted via solder (adhesive) SF. In particular, on the back of the semiconductor chip CHP1, the back electrode BE is formed, which is in direct contact with the solder SF. Meanwhile, on the surface of the semiconductor chip CHP1, the source electrode (a source pad) SE electrically coupled to the source of the power MOSFET formed in the semiconductor chip CHP1 and a gate pad GP electrically coupled to the gate electrode of the power MOSFET are formed. Also, a surface protection film PAS is formed by a silicon oxide film or a silicon nitride film, for example, to cover the source electrode SE and the gate pad GP, as illustrated in FIG. 18. An opening is formed in a portion of this surface protection film PAS. Further, the gate pad GP is electrically coupled to the lead LD1 via wire W, as illustrated in FIG. 18, for example. Similarly, the source electrode SE is also electrically coupled to the other lead LD2 via wire W.

A sealing member MR, made of epoxy resin, for example, is then formed to cover the semiconductor chip CHP1 and the wire W, as illustrated in FIG. 18. In this manner, the semiconductor device PKG1 in this first embodiment is formed.

### <Structural Features in First Embodiment>

A structural feature of the semiconductor chip CHP1 in this first embodiment is that the side face SUR3 of the semiconductor chip CHP1 includes the slant portion SLP1 and the side face SUR4 of the semiconductor chip CHP1 includes the slant portion SLP2, as illustrated in FIG. 16, for example. Due to this feature, the cross-sectional shape of the semiconductor chip CHP1 in this first embodiment is approximately trapezoidal, as illustrated in FIG. 16, and a structure in which the plane area of the back SUR2 of the semiconductor chip CHP1 is larger than the plane area of the surface SUR1 can be achieved.

This structural feature is naturally formed by employing the aforementioned manufacturing method (FIGS. 9 to 15) of the semiconductor device in this first embodiment basically. Further, this feature also provides advantages unique to the structure. In the following description, the structural advantages caused by this feature are described.

The first advantage is obtained by the angle formed by the surface SUR1 of the semiconductor chip CHP1 and the side face (SUR3, SUR4) being an obtuse angle (an angle larger than 90°), as illustrated in FIG. 16, for example, because of the structural feature in this first embodiment. For example, chipping of the semiconductor chip CHP1 is one of factors causing a failure of the semiconductor chip CHP1. This chipping can more easily occur at a corner having an angle that is an obtuse angle, i.e., is larger than 90° than at a corner having an angle that is an acute angle, i.e., is smaller than 90°. In regard to this point, in this first embodiment, an angle of a corner of the semiconductor chip CHP1 on the surface SUR1 side is an obtuse angle, as illustrated in FIG. 16. This means that chipping at the corner of the semiconductor chip CHP1 on the surface SUR1 side is suppressed. In particular, the element portion of the power MOSFET is formed on the surface side of the semiconductor chip CHP1 and therefore the chipping at the corner of the semiconductor chip CHP1 on the surface SUR1 side directly leads to a failure of the power MOSFET. That is, the chipping at the corner of the semiconductor chip CHP1 on the surface SUR1 side has a large adverse effect on the power MOSFET. Therefore, it is especially important to suppress the chipping at the corner of the semiconductor chip CHP1 on the surface SUR1 side. In regard to this point, with the structural feature in this first embodiment, the angle of the corner on the surface SUR1 side becomes an obtuse angle, as illustrated in FIG. 16, so that the chipping at the corner of the semiconductor chip CHP1 on the surface SUR1 side can be effectively suppressed.

Meanwhile, in the semiconductor chip CHP1 in this first embodiment, an angle of a corner on the back SUR2 side becomes an acute angle, and therefore there are concerns that chipping occurs at the corner on the back SUR2 side. In regard to this point, because the back SUR2 side of the semiconductor chip CHP1 is away from the element portion of the power MOSFET, the chipping at the corner on the back SUR2 side has a small effect on the power MOSFET, which is not a large problem. It is more important to suppress the chipping at the corner of the semiconductor chip CHP1 on the surface SUR1 side than on the back SUR2 side.

From the above, according to the semiconductor chip CHP1 in this first embodiment, the chipping at the corner on the surface SUR1 side, which is fatal to the power MOSFET, is largely suppressed. Therefore, it is possible to obtain the advantage that the semiconductor device with the high reliability can be provided.

The second advantage is that a temperature cycle resistance can be improved. For example, the semiconductor chip CHP1 is finally incorporated into a package structure (the semiconductor device PKG1) illustrated in FIG. 18. Then, a temperature cycle test and the like are performed for the semiconductor device PKG1 in order to guarantee the reliability, and thereafter a non-defective product that has passed this test is shipped. In the temperature cycle test, the resin forming the sealing member MR illustrated in FIG. 18 expands and contracts, and therefore a stress is applied to the semiconductor chip CHP1 covered with the sealing member MR. In particular, it is more likely that a large stress is applied to a corner (an end) of the semiconductor chip CHP1. In regard to this point, because the angle of the corner on the surface SUR1 side is an obtuse angle in the semiconductor chip CHP1 in this first embodiment, a stress applied to the corner on the surface SUR1 side is distributed. Therefore, in the semiconductor chip CHP1 in this first embodiment, even when expansion and contraction of the sealing member ME occur in the temperature cycle test, the stress applied to the semiconductor chip CHP1 is reduced. This means that the temperature cycle resistance can be improved according to the semiconductor chip CHP1 in this first embodiment, and enables reduction of a defective product of the semiconductor device PKG1. Therefore, according to the semiconductor device PKG1 in this first embodiment, the manufacturing yield can be improved, so that the manufacturing cost of the semiconductor device PKG1 can be reduced.

The third advantage is that a heat dissipation efficiency can be improved because of the size of the back SUR2 of the semiconductor chip CHP1 larger than the size of the surface SUR1 of the semiconductor chip CHP1, as illustrated in FIG. 16. Specifically, the semiconductor chip CHP1 is arranged on the chip-mounting portion TAB, as illustrated in FIG. 18. The semiconductor chip CHP1 includes the power MOSFET formed therein, and has a property that the semiconductor chip CHP1 can easily generate heat because a large current flows through the power MOSFET. When the semiconductor chip CHP1 generates heat to increase the temperature of the semiconductor device CHP1, thermal runaway of the power MOSFET is caused. Therefore, in order to ensure a stable operation of the power MOSFET formed in the semiconductor chip CHP1, it is important to improve the efficiency of heat dissipation from the semiconductor chip CHP1. In regard to this point, with the structural feature in this first embodiment, the area of the back SUR2 of the semiconductor chip CHP1 becomes large. This means that, as is apparent from FIG. 18, for example, an area of contact between the semiconductor chip CHP1 and the chip-mounting portion TAB becomes large. In particular, the chip-mounting portion TAB is formed of metal material having a high thermal conductivity. Therefore, increase of the area of contact between the semiconductor chip CHP1 and the chip-mounting portion TAB means improvement of the efficiency of heat dissipation from the semiconductor chip CHP1 to the chip-mounting portion TAB. Thus, according to this first embodiment, it is possible to improve the heat dissipation efficiency of the heat generated in the semiconductor chip CHP1. Consequently, a remarkable effect that the reliability of the semiconductor device PKG1 can be improved can be obtained according to this first embodiment.

According to the semiconductor chip CHP1 in this first embodiment, the inclination angle θ illustrated in FIG. 16 becomes an acute angle (an angle smaller than 90°). However, from reasons described below, it is desirable that the inclination angle θ is not too small. The first reason is as follows. In a case where the inclination angle θ is too small, the solder SF interposed between the semiconductor chip CHP1 and the chip-mounting portion TAB can easily creep up along the slant portion (SLP1, SLP2) illustrated in FIG. 16 when the semiconductor chip CHP1 is mounted on the chip-mounting portion TAB. That is, the solder SF that has creeped up causes a short-circuit failure between the back electrode BE formed on the back SUR2 and the source electrode SE formed on the surface SUR1. Therefore, it is desirable that the inclination angle θ is not too small.

The second reason is as follows. When the inclination angle θ becomes too small, the size of the surface SUR1 is also reduced. The size reduction of the surface SUR1 means the size increase of a scribing region in the semiconductor substrate 1S (the semiconductor wafer WF), and this means that the number of the semiconductor chips CHP1 that can be obtained from the semiconductor substrate 1S is reduced. That is, as the inclination angle θ becomes too small, the number of the semiconductor chips CHP1 that can be obtained from the semiconductor substrate 1S (the semiconductor wafer WF) is reduced, resulting in difficulty in reducing the manufacturing cost of the semiconductor chips CHP1. From the above, it is desirable that the inclination angle θ of the semiconductor chip CHP1 is not too small.

### <First Modification>

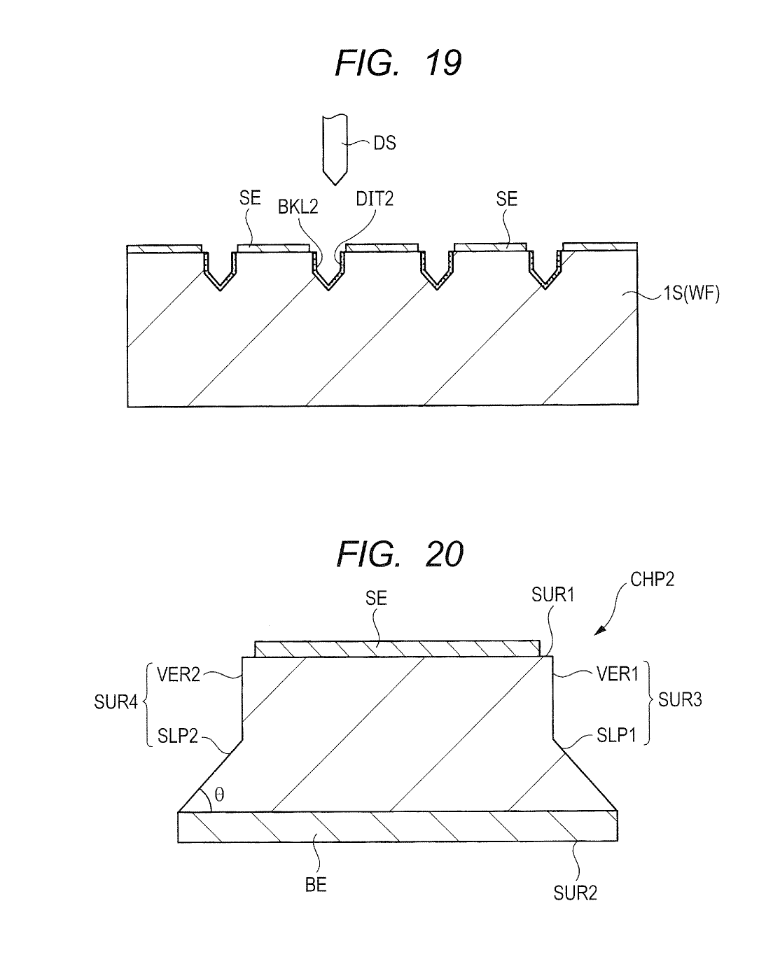

Next, a first modification of the first embodiment is described. In particular, the description is made mainly to differences between the first embodiment and this first modification. In the manufacturing method of the semiconductor device in the first embodiment, the cross-sectional shape of the groove DIT1 formed on the surface side of the semiconductor substrate 1S is an inverted triangular shape, as illustrated in FIG. 10. On the other hand, in a manufacturing method of a semiconductor device in this first modification, a cross-sectional shape of a groove DIT2 is configured by a shape obtained by combining the inverted triangular shape and a vertical shape, as illustrated in FIG. 19. That is, the cross-sectional shape of the groove DIT2 formed in the manufacturing method of the semiconductor device in this first modification is configured to include an inverted tapered shape when seen with an element-forming face facing up and the vertical shape that is vertical to the surface of the semiconductor substrate 1S. This shape is formed due to a shape of a tip of a dicing blade illustrated in FIG. 19. That is, by changing the shape of the tip of the dicing blade DS, it is possible to form the groove DIT1 having the cross-sectional shape illustrated in FIG. 10 or form the groove DIT2 having the cross-sectional shape illustrated in FIG. 19.

### <Structure of Semiconductor Chip in First Modification>

FIG. 20 is a cross-sectional view illustrating a schematic structure of a semiconductor chip CHP2 manufactured by the manufacturing method of the semiconductor device in this first modification. As illustrated in FIG. 20, a semiconductor chip CHP2 in the first modification includes the side face SUR3 coupled to each of the surface SUR1 and the back SUR2 and the side face SUR4 located on the opposite side of the side face SUR3. The side face SUR3 is formed by a vertical-shape portion VER1 that is vertical to the surface SUR1 and the slant portion SLP1 that is inclined with respect to the back SUR2. Similarly, the side face SUR4 is formed by a vertical-shape portion VER2 that is vertical to the surface SUR1 and the slant portion SLP2 that is inclined with respect to the back SUR2. In the semiconductor chip CHP2 in this first modification, the inclination angle θ formed by the slant portion SLP1 (SLP2) and the back SUR2 can be set to 10° or more and 40° or less, for example. As specific examples, in a case where the thickness of the semiconductor chip CHP2 is about 40 μm, the inclination angle θ is about 20° to 40°. In a case where the thickness of the semiconductor chip CHP2 is about 30 μm, the inclination angle θ is about 15° to 35°. In a case where the thickness of the semiconductor chip CHP2 is about 20 μm, the inclination angle θ is about 10° to 25°.

### <Features Unique to First Modification>

A feature unique to the semiconductor chip CHP2 in this first modification is that the side face SUR3 is formed by the slant portion SLP1 and the vertical-shape portion VER1 and the side face SUR4 is formed by the slant portion SLP2 and the vertical-shape portion VER2, as illustrated in FIG. 20, for example. Due to this feature, as in the structure in which the semiconductor chip CHP1 is mounted on the chip-mounting portion TAB via the solder SF like the package structure in the first embodiment illustrated in FIG. 18, for example, the semiconductor chip CHP2 is mounted on the chip-mounting portion TAB via the solder SF also in the package structure in the first modification. The side face SUR3 (SUR4) has the vertical-shape portion VER1 (VER2) according to the feature unique to this first modification. Therefore, even if the protruding solder SF has creeped up along the slant portion SLP1 (SLP2) of the side face SUR3 (SUR4) when the semiconductor chip CHP2 is mounted on the chip-mounting portion TAB via the solder SF, the vertical-shape portion VER1 (VER2) can suppress the solder SF from further creeping up. Consequently, according to this first modification, it is possible to prevent the solder SF that has creeped up on the side face SUR3 (SUR4) from reaching the surface SUR1, so that a short-circuit failure between the back electrode BE and the source electrode SE via the solder SF can be prevented.

### <Second Modification>

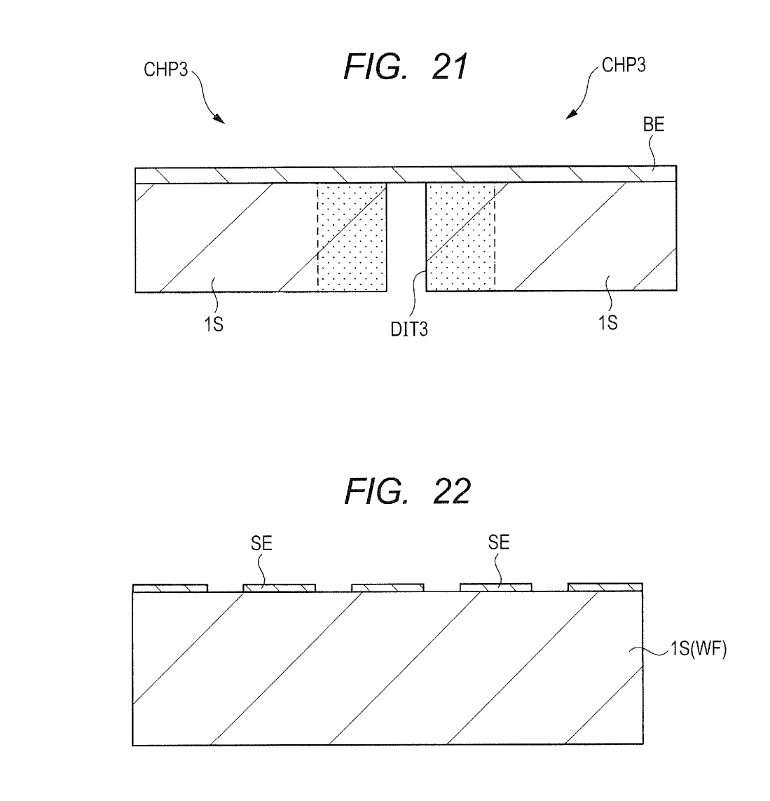

Next, a second modification in the first embodiment is described. In a manufacturing method of a semiconductor device in this second modification, as illustrated in FIG. 21, for example, the width (Kerf width) of a groove DIT3 formed on the surface side of the semiconductor substrate 1S (a lower-side face in FIG. 21) is made small. Due to this configuration, the groove DIT3 is blocked by the back electrode BE when the back electrode BE is formed on the back (an upper face in FIG. 21) of the semiconductor substrate 1S, as illustrated in FIG. 21, and therefore formation of the back electrode BE on side faces of the groove DIT3 can be prevented. That is, in the second modification, to “make the width of the groove DIT3 smaller” means to reduce the width of the groove DIT3 to a such a width that the groove DIT3 can be blocked by the back electrode BE. Thus, according to the second modification, it is possible to prevent a short-circuit failure caused by formation of the back electrode BE on the side faces of the groove DIT3.

The summary of a manufacturing method of the thus configured semiconductor device in this second modification is described below. In the manufacturing method of the semiconductor device in this second modification, a cross-sectional shape of the groove DIT3 formed in the semiconductor substrate 1S is formed by a vertical-shape portion that is vertical to the surface of the semiconductor substrate 1S. By grinding the semiconductor substrate 1S from the back side thereof until the ground face reaches the groove DIT3, a plurality of chip regions are separated from each other into a plurality of semiconductor chips CHP3. Thereafter, the back electrode BE is formed on the back of the separated semiconductor substrate 1S. The back electrode BE formed in this step blocks the grooves DIT3 and is integrally formed with respect to the back of the separated semiconductor substrate 1S. The manufacturing method of the semiconductor device in this second modification further includes an expansion step that broadens gaps between the semiconductor chips CHP3. Consequently, the respective semiconductor chips CHP3 are mutually coupled by the back electrode BE formed on the respective backs of the semiconductor chips CHP3, but are separated from each other by the expansion step performed thereafter.

According to the manufacturing method of the thus configured semiconductor device in this second modification, as a result of making the width (Kerf width) of the groove DIT3 small, the width of a scribing region in the semiconductor substrate 1S (the semiconductor wafer) can be made small. This means that an occupied area of the scribing region to the entire area of the semiconductor substrate 1S can be reduced. This in turn means that it is possible to increase the yield of the semiconductor chips CHP3 that can be obtained from the semiconductor substrate 1S (the semiconductor wafer). Therefore, according to the manufacturing method of the semiconductor device in this second modification, the manufacturing cost of the semiconductor device can be reduced.

### Second Embodiment

### <Manufacturing Method of Semiconductor Device in Second Embodiment>

Next, a manufacturing method of a semiconductor device in this second embodiment is described, referring to the drawings. First, as illustrated in FIG. 22, the semiconductor substrate 1S, for example, made of silicon (the semiconductor wafer WF) is prepared. A device structure of a “power transistor” is then formed on a surface side (an element-forming face side) of the semiconductor substrate 1S. The semiconductor substrate 1S includes a plurality of chip regions sectioned by scribing regions that serve as boundary regions, and in each of the chip regions, the “power transistor” (semiconductor element) is formed. In particular, in FIG. 22, the device structure of the “power transistor” formed on the surface side of the semiconductor substrate 1S is omitted, whereas the source electrode SE electrically coupled to a source of the “power transistor” is illustrated. This source electrode SE is formed by an aluminum film or an aluminum alloy film, for example, and is formed by depositing the aluminum film on the semiconductor substrate 1S and then patterning the aluminum film by using photolithography and etching, for example.

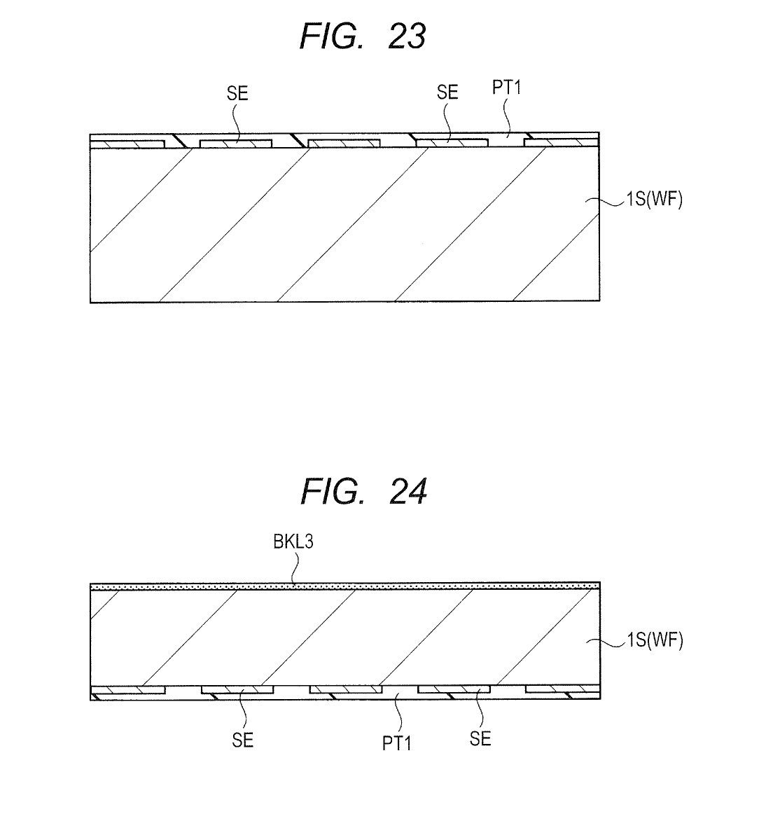

Next, as illustrated in FIG. 23, the surface protection tape PT1 is put onto the surface of the semiconductor substrate 1S on which the source electrode SE is formed. Thereafter, as illustrated in FIG. 24, the semiconductor substrate 1S is ground from a back side thereof until the thickness of the semiconductor substrate 1S becomes a first thickness. For example, the first thickness is about 100 μm to 600 μm. In this grinding, a broken layer BKL3 caused by the grinding is formed on the back of the semiconductor substrate 1S, as illustrated in FIG. 24.

A reformed layer RFL is then formed inside the semiconductor substrate 1S in the boundary regions sectioning the chip regions, as illustrated in FIG. 25. Specifically, the reformed layer RFL can be formed by radiation of laser from the back side of the semiconductor substrate 1S into the semiconductor substrate 1S.

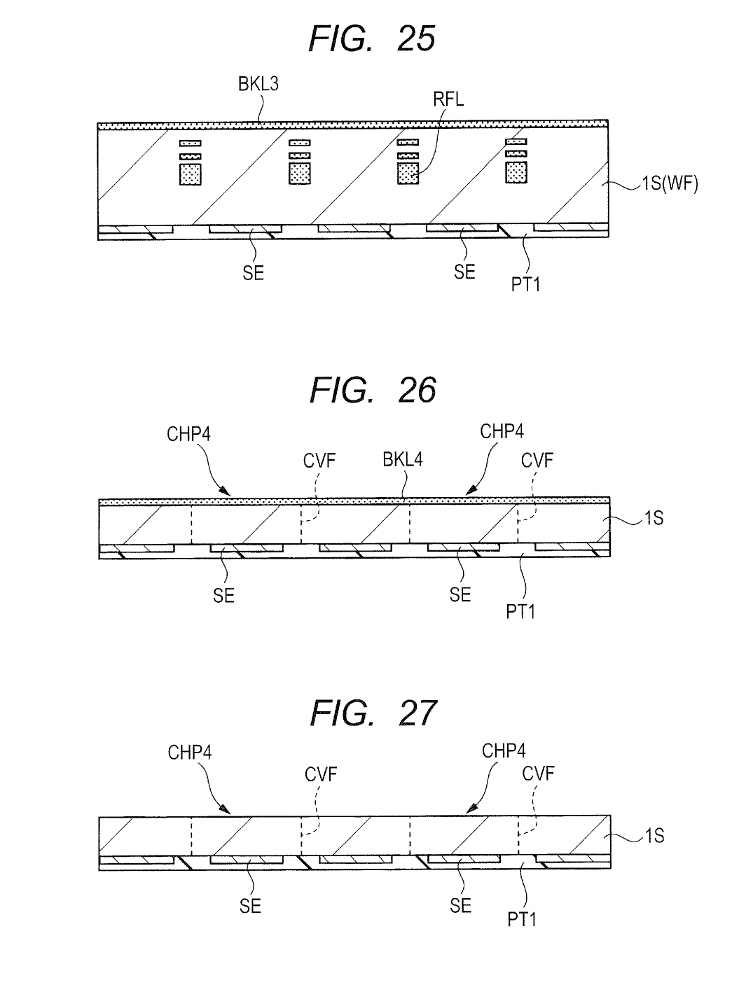

Subsequently, as illustrated in FIG. 26, the semiconductor substrate 1S is ground from the back side thereof until the thickness of the semiconductor substrate 1S becomes a second thickness. This causes cleavage originating from the reformed layer RFL, so that the chip regions are separated into a plurality of semiconductor chips CHP4. That is, in FIG. 26, when grinding is performed from the back side of the semiconductor substrate 1S, cleavage occurs from the reformed layer RFL because of stress during the grinding, so that the semiconductor substrate 1S is separated by a cleavage face CVF. Further, a broken layer BKL4 is formed by grinding on the back of the separated semiconductor substrate 1S. At this time, the reformed layer RFL itself is removed by grinding. That is, the reformed layer RFL does not remain in the separated semiconductor chips CHP4.

The broken layer BKL4, formed on the back of the semiconductor substrate 1S separated by the cleavage faces CVF, is then removed, as illustrated in FIG. 27. Specifically, a broken-layer removal step is performed by a plasma process using a gas. Because a wet process is not used in the broken-layer removal step also in this second embodiment, it is possible to prevent a chemical liquid from entering into the cleavage faces CVF, so that a failure of the “power transistor” formed in the semiconductor substrate 1S can be prevented.

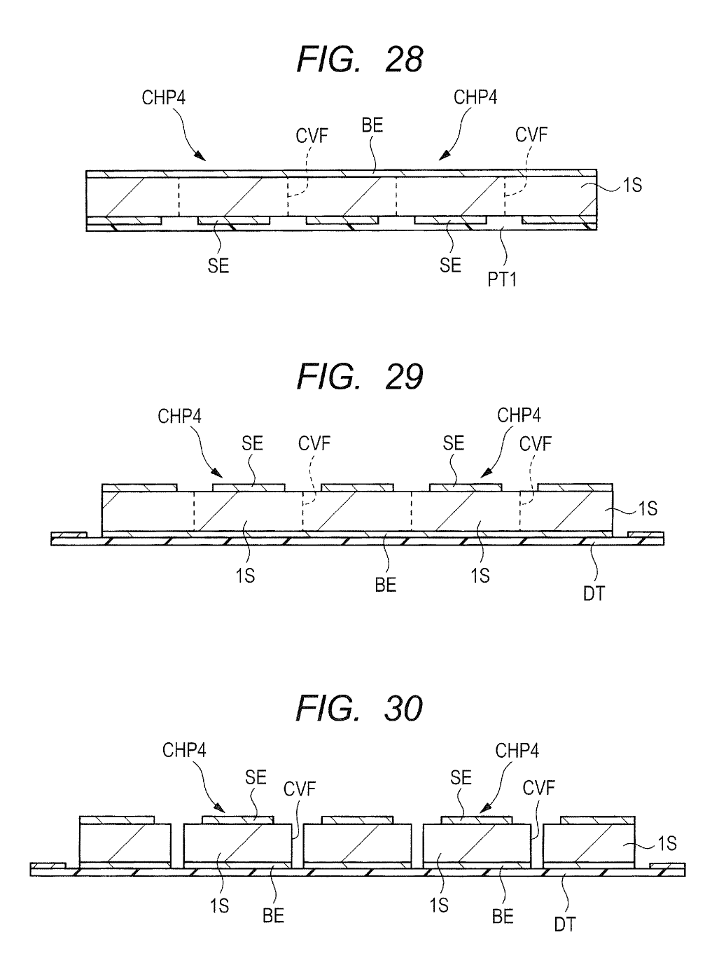

Thereafter, as illustrated in FIG. 28, the back electrode BE that is integrally formed to spread over backs of the semiconductor chips CHP4 is formed. Subsequently, the semiconductor chips CHP4 coupled by the back electrode BE are arranged on the dicing tape DT in such a manner that the back electrode BE is in contact with the dicing tape DT, as illustrated in FIG. 29. Then, as illustrated in FIG. 30, the dicing tape DT is stretched to broaden gaps between the semiconductor chips CHP4, thereby separating the integrally formed back electrode BE into pieces corresponding to the respective semiconductor chips CHP4. In the above-described manner, the semiconductor chip CHP4 in this second embodiment can be obtained.

### <Feature in Manufacturing Method in Second Embodiment>

According to the manufacturing method of the semiconductor device in this second embodiment, the following advantages can be obtained. As illustrated in FIG. 27, according to the manufacturing method of the semiconductor device in this second embodiment, the semiconductor substrate 1S is separated into the semiconductor chips CHP4 by the cleavage faces CVF. Thus, it is possible to separate the semiconductor chips CHP4 from each other without generating gaps between the semiconductor chips CHP4. From this, it is possible to prevent the back electrode BE from entering to a side face of the semiconductor chip CHP4 in the step of forming the back electrode illustrated in FIG. 28, for example. Therefore, according to the manufacturing method of the semiconductor device in this second embodiment, it is possible to prevent a short-circuit failure between the back electrode BE and the source electrode SE of the semiconductor chip CHP4 caused by formation of the back electrode BE also on the side face, so that the reliability of the semiconductor device can be improved.

Also, according to this second embodiment, the semiconductor chips CHP4 are separated from each other by cleavage. Therefore, the scribing regions in the semiconductor substrate 1S can be made small. This can increase the number of the semiconductor chips CHP4 obtained from the semiconductor substrate 1S. Therefore, according to this second embodiment, the manufacturing cost of the semiconductor device can be reduced.

Further, according to the manufacturing method of the semiconductor device in this second embodiment, the reformed layer RFL is removed by the step of grinding until the thickness of the semiconductor substrate 1S becomes the second thickness. Therefore, the reformed layer RFL does not remain inside the semiconductor chip CHP4. This can suppress lowering of the mechanical strength of silicon (Si) caused by the reformed layer RFL.

### <Structural Feature in Second Embodiment>

According to the aforementioned manufacturing method of the semiconductor device in this second embodiment, the semiconductor chip CHP4 having the following structure can be obtained. The semiconductor chip CHP4 in this second embodiment includes the surface on which the “power transistor” (semiconductor element) is formed, the back located on the opposite side of the surface, on which a back electrode is formed, a first side face coupled to each of the surface and the back, a second side face located on the opposite side of the first side face, a third side face coupled to each of the first side face and the second side face, and the fourth side face located on the opposite side of the third side face. Each of the first side face and the second side face is formed by a cleavage face, and each of the third side face and the fourth side face is formed by a cleavage face. Due to this configuration, according to the semiconductor chip CHP4 in this second embodiment, the mechanical strength of the semiconductor chip CHP4 can be improved. This is because a broken layer that is a factor lowering the mechanical strength is not formed as a result of forming of the side faces (the first side face to the fourth side face) of the semiconductor chip CHP4 by the cleavage faces. In particular, in a case where the semiconductor chip CHP4 becomes very thin, the mechanical strength of the semiconductor chip CHP4 strongly depends on the strength of the side face of the semiconductor chip CHP4. In regard to this point, according to the semiconductor chip CHP4 in this second embodiment, all the side faces of the semiconductor chip CHP4 are formed by the cleavage faces that are strong in mechanical strength, and therefore the mechanical strength of the semiconductor chip CHP4 can be improved even in a case where the semiconductor chip CHP4 is further thinned. From this, according to this second embodiment, the reliability of the semiconductor device can be improved.

A technical idea in this second embodiment is not limited to a case using the semiconductor substrate 1S made of silicon, but can be also applied widely to a case of using a semiconductor substrate 1S made of compound semiconductor, typified by gallium nitride (GaN), for example. In particular, the compound semiconductor typified by gallium nitride (GaN) is direct-transition semiconductor and is therefore suitable for manufacturing a semiconductor laser with a high light-emission efficiency. Further, because the semiconductor laser uses the cleavage face for including a resonator, the technical idea in this second embodiment that includes the side faces of the semiconductor chip by the cleavage faces is useful in that this technical idea is applicable to manufacturing of a semiconductor chip in which the semiconductor laser is formed.

In the above, the invention made by the inventors of the present application has been specifically described by way of the embodiments. However, it is naturally understood that the present invention is not limited to the aforementioned embodiments, and can be changed in various ways within the scope not departing from the gist thereof.

### <Usability of Technical Idea in Embodiments>

The technical idea in the embodiments is to provide a technique of separating “thinned semiconductor chips with a back electrode formed thereon” that can be hardly achieved by conventional blade dicing. Therefore, according to the technical idea in the embodiments, it is possible to deal with thinning of a semiconductor chip with a “power transistor” formed thereon, for example, so that the “power transistor” with a small on-state resistance can be achieved. In particular, in the semiconductor chip in which the “power transistor” is formed, an epitaxial layer is formed on a semiconductor substrate and an impurity concentration in the semiconductor substrate is increased in order to reduce the on-state resistance. However, in a case of using a semiconductor wafer with a large diameter, typified by a 300-mm wafer, an effect of a variation in the impurity concentration becomes large. This makes it difficult to achieve a high-concentration semiconductor wafer. Therefore, in this case, the on-resistance has to be reduced by reducing the thickness of “the semiconductor layer plus the epitaxial layer”. In regard to this point, the usability of the technical idea that provides the technique of separating “the thinned semiconductor chips with the back electrode formed thereon”, which is difficult to achieve by the conventional blade dicing, becomes larger. Further, according to the technical idea in the embodiments, it is also possible to achieve a so-called “substrate-less chip” in which the semiconductor substrate is not left. In particular, even in a case of using the large-diameter semiconductor wafer for which a high-concentration semiconductor wafer is difficult to achieve, the “substrate-less chip” can be achieved by using the technical idea in the embodiments. That is, according to the technical idea in the embodiments, without using the high-concentration semiconductor wafer, it is possible to achieve reduction of the on-state resistance by using the large-diameter semiconductor wafer and employing the “substrate-less chip” structure. Consequently, the technical idea in the embodiments is a highly usable technical idea in that it has a potential of being capable of achieving a semiconductor chip with a small on-resistance and a high-performance “power transistor” formed thereon at a low manufacturing cost.

The aforementioned embodiment includes the following form.

### APPENDIX

A semiconductor device includes a semiconductor chip, in which the semiconductor chip includes: a surface on which a semiconductor element is formed; a back located on the opposite side of the surface, on which a back electrode is formed; a first side face coupled to each of the surface and the back; a second side face located on the opposite side of the first side face; a third face coupled to each of the first side face and the second side face; and a fourth side face located on the opposite side of the third side face, and each of the first side face and the second side face is formed by a cleavage face, and each of the third side face and the fourth side face is formed by a cleavage face.

What is claimed is:

1. A manufacturing method of a semiconductor device, comprising the steps of:
(a) forming elements on a surface side of a substrate having a plurality of chip regions;
(b) forming grooves in boundary regions that section the chip regions;
(c) grinding the substrate to the grooves, from a back side of the substrate; and
(d) forming a back electrode on a back of the substrate separated in the step (c).

2. The manufacturing method of the semiconductor device according to claim 1,
wherein a cross-sectional shape of the grooves formed in the step (b) includes an inverted tapered shape, when seen with the surface of the substrate facing up, and
wherein the chip regions are separated into a plurality of semiconductor chips in the step (c).

3. The manufacturing method of the semiconductor device according to claim 2,
wherein the cross-sectional shape of the grooves is an inverted trapezoidal shape or an inverted triangular shape, when seen with the surface of the substrate facing up.

4. The manufacturing method of the semiconductor device according to claim 2,
wherein when attention is paid to first and second ones of the semiconductor chips separated in the step (c), that are adjacent to each other, a distance between a back of the first semiconductor chip and a back of the second semiconductor chip is smaller than a distance between an element-forming face of the first semiconductor chip and an element-forming face of the second semiconductor chip.

5. The manufacturing method of the semiconductor device according to claim 2,
wherein the back electrodes formed on the respective semiconductor chips are separated from each other in the step (d).

6. The manufacturing method of the semiconductor device according to claim 2, further comprising an expansion step that broadens gaps between the semiconductor chips after the step (d),
wherein in a case where the back electrodes formed on the respective semiconductor chips are continuous in the step (d), the back electrodes formed on the respective semiconductor chips are separated from each other by the expansion step.

7. The manufacturing method of the semiconductor device according to claim 2, further comprising a processing strain removal step that removes processing strain formed on the back of the separated substrate and side faces of the grooves after the step (c) and before the step (d).

8. The manufacturing method of the semiconductor device according to claim 7,
wherein the processing strain removal step uses a plasma process.

9. The manufacturing method of the semiconductor device according to claim 2,
wherein an inclination angle that is an angle between a side face of the grooves and the back is 25° or more and 85° or less.

10. The manufacturing method of the semiconductor device according to claim 1,
wherein the elements are power transistors.

11. The manufacturing method of the semiconductor device according to claim 1,
wherein a cross-sectional shape of the grooves formed in the step (b) includes an inverted tapered shape and a vertical shape that is vertical to the surface of the substrate, when seen with the surface of the substrate facing up.

12. The manufacturing method of the semiconductor device according to claim 11,
wherein an inclination angle that is an angle between a side face of the grooves and the back is 10° or more and 40° or less.

13. The manufacturing method of the semiconductor device according to claim 1,
wherein the cross-sectional shape of the grooves formed in the step (b) is configured by a vertical-shape portion that is vertical to the surface of the substrate,
wherein in the step (c), the chip regions are separated from each other into a plurality of semiconductor chips,
wherein the manufacturing method of the semiconductor device further includes an expansion step that broadens gaps between the semiconductor chips after the step (d), and
wherein the respective semiconductor chips separated in the step (c) are mutually coupled by the back electrode formed on backs of the respective semiconductor chips and are thereafter separated from each other by the expansion step.

14. A manufacturing method of a semiconductor device, comprising the steps of:
(a) forming elements on a surface side of a substrate including a plurality of chip regions;
(b) grinding the substrate from a back side thereof until a thickness of the substrate becomes a first thickness;
(c) forming a reformed layer inside the substrate in boundary regions that section the chip regions, after the step (b);
(d) grinding the substrate from the back side thereof until the thickness of the substrate becomes a second thickness after the step (c), to cause cleavage originating from the reformed layer so that the chip regions are separated from each other into a plurality of semiconductor chips;
(e) forming a back electrode united to spread over backs of the semiconductor chips after the step (d); and
(f) broadening gaps between the semiconductor chips after the step (e), to separate the united back electrode into pieces respectively corresponding to the semiconductor chips.

15. The manufacturing method of the semiconductor device according to claim 14,
wherein in the step (c), laser is radiated to the substrate from the back side of the substrate.

16. The manufacturing method of the semiconductor device according to claim 14, wherein in the step (d), the reformed layer is removed from the substrate by the grinding of the substrate until the thickness of the substrate becomes the second thickness.

17. A semiconductor device comprising a semiconductor chip,
wherein the semiconductor chip includes:
a surface where a semiconductor element is formed; and
a back located on an opposite side of the surface, on which a back electrode is formed, and
wherein a plane area of the back is larger than a plane area of the surface.

18. The semiconductor device according to claim 17,
wherein the semiconductor chip includes:
a first side face coupled to each of the surface and the back; and
a second side face located on an opposite side of the first side face, and
wherein the first side face includes a first slant portion inclined with respect to each of the surface and the back, and
wherein the second side face includes a second slant portion inclined with respect to each of the surface and the back.

19. The semiconductor device according to claim 17,
wherein the semiconductor chip includes:
a first side face coupled to each of the surface and the back; and
a second side face located on an opposite side of the first side face, and
wherein the first side face is configured by a first vertical-shape portion that is vertical to the surface and a first slant portion inclined with respect to the back, and
wherein the second side face is configured by a second vertical-shape portion that is vertical to the surface and includes a second slant portion inclined with respect to the back.
